(19) United States
(12) Patent Application Publication
(10) Pub. No.: US 2013/0293859 A1
(43) Pub. Date: Nov. 7, 2013

(54) LARGE FIELD PROJECTION OBJECTIVE FOR LITHOGRAPHY

(71) Applicants: Heng Wu, Shanghai (CN); Ling Huang, Shanghai (CN); Guogan Liu, Shanghai (CN)

(72) Inventors: Heng Wu, Shanghai (CN); Ling Huang, Shanghai (CN); Guogan Liu, Shanghai (CN)

(73) Assignee: SHANGHAI MICRO ELECTRONICS EQUIPMENT CO., LTD, Shanghai (CN)

(21) Appl. No.: 13/976,353

(22) PCT Filed: Dec. 7, 2011
(86) PCT No.: PCT/CN2011/083616

§ 371 Date: Jun. 26, 2013

(30) Foreign Application Priority Data
Dec. 31, 2010 (CN) 201010619283.X

(51) Int. Cl. G03F 7/20

(52) U.S. Cl. CPC G03F 7/7015
USPC 355/55

(57) ABSTRACT

A lithography projection objective (30) for focusing and imaging a pattern of a reticle onto a wafer including, from the reticle and along an optical axis: a first lens group G31 having a positive refractive power; a second lens group G32 having a positive refractive power; a third lens group G33 having a positive refractive power; and a fourth lens group G34 having a positive refractive power. These four lens groups form a 2× magnification design which has a partial field of view of not smaller than 100 mm; a wavelength band of I-line±5 nm can ensure a sufficient exposure light intensity. Moreover, the present invention also achieves, with a relatively simple structure, the demanded millimeter-level resolution as well as the correction of distortions, field curvatures, astigmatisms and chromatic aberrations in a large field.

### TECHNICAL FIELD

The present invention relates in general to semiconductor processing technologies, and more particularly, to a large field projection objective for use in projection optical systems of lithography tools.

### BACKGROUND

Currently, in the field of semiconductor processing, there are increasing demands for high-throughput projection optical systems with millimeter-level resolution. In order to obtain a high throughput, stepper-type lithography tools generally adopt a large exposure field. Moreover, in order to be adapted for reticle size, some of them employ optical systems with a magnification of 1.25× or 1.6×.

Japanese patent publication No.2000199850 discloses a 1.6× projection objective for lithography using exposure light with a wavelength of G-line or H-line and having a 117.6 mm field of view and a numerical aperture (NA) of 0.1 on a wafer surface. The projection objective is a multi-lens system consisting of 38 lenses and including an aspheric surface.

Moreover, Japanese patent publication No. 2006267383 discloses a 1.25× projection objective for lithography using I-line with a wavelength band of ±3 nm as the exposure light and has a partial field of 93.5 mm

Furthermore, Japanese patent publication No. 2007079015 discloses another 1.25× projection objective also using I-line with a wavelength band of +1.5 nm as the exposure light and has a partial field of 93.5 mm.

Indicated as above, such large exposure field design is dominant in the field of liquid crystal display (LCD) lithography tool, and meanwhile, in order to be adapted for reticle size, many optical systems adopt projection objectives with a magnification of higher than 1×, and even close to 2×. According to these conventional technologies in combination with consideration of indeed demands, there is a need to develop a projection objective with a magnification of 2×.

### SUMMARY OF THE INVENTION

The present invention is directed to the provision of a large field projection objective which is able to correct multiple types of aberrations, in particular, distortions, field curvatures, astigmatisms, axial chromatic aberrations and magnification chromatic aberrations, and obtain telecentricity both on the object and image sides.

In one embodiment, a projection objective for lithography which focuses and images a pattern of a reticle onto a wafer successively comprises, from the reticle and along an optical axis: a first lens group G31 having a positive refractive power; a second lens group G32 having a positive refractive power; a third lens group G33 having a positive refractive power; and a fourth lens group G34 having a positive refractive power, wherein following formulae are satisfied:

1.8<|fG32/fG31|<5.4

0.57<|fG33/fG34|<0.97

0.19<|IfG33/fG32|<0.5

where f_{G31} is a focal length of the first lens group G31, f_{G32} is a focal length of the second lens group G32, f_{G33} is a focal length of the third lens group G33, and f_{G34} is a focal length of the fourth lens group G34.

Preferably, the first lens group G31 comprises at least four lenses. Additionally, the second lens group G32 comprises at least six lenses and includes at least two pairs of lenses each consisting of a positive lens and a negative lens adjacent to the positive lens. Moreover, the third lens group G33 comprises at least four lenses and includes a sub-lens group G33-1n having a positive refractive power, the sub-lens group G33-1n including at least two adjacent lenses of the third lens group G33 both of which have a positive refractive power. Furthermore, the fourth lens group G34 comprises at least six lenses and includes a sub-lens group G34-1n having a positive refractive power, the sub-lens group G34-1n including at least three directly successively arranged lenses of the fourth lens group G34 all of which have a positive refractive power. The following formulae are satisfied:

1.03<|fₑₗ_{_{—}}ₘₐₓ/f_{G31}|<1.95

0.34<|f_{G33-1n}/f_{G33}|<0.87

0.21<|f_{G34-1n}/f_{G34}|<0.47

where fₑₗ_{_{—}}ₘₐₓ is a focal length of a lens of the first lens group G31 which has a greatest refractive power in the first lens group G31, f_{G33-1n} is a focal length of the sub-lens group G33-1n of the third lens group G33, and f_{G34-1n} is a focal length of the sub-lens group G34-1n of the fourth lens group G34.

Preferably, the second lens group G32 includes at least a positive lens and a negative lens directly adjacent to the positive lens and the following formula is satisfied:

1.23<V_{G32-p}/V_{G32-N}<1.85

where V_{G32-p} is an Abbe number of the positive lens of the second lens group G32, and V_{G32-N} is an Abbe number of the negative lens of the second lens group G32 that is directly adjacent to the positive lens.

Preferably, the second lens group G32 includes at least a positive lens and a negative lens directly adjacent to the positive lens, and the following formula is satisfied:

b 1.59<V_{G32-P}/V_{G32-N}<2.65

where V_{G32-P} is an Abbe number of the positive lens of the second lens group G32, and V_{G32-N} is an Abbe number of the negative lens of the second lens group G32 that is directly adjacent to the positive lens.

Preferably, the two adjacent positive lenses of the sub-lens group G33-1n of the third lens group G33 satisfy the following formula:

0.75<f₄₁<f₄₂1

where f₄₁ is a focal length of the lens disposed upstream in the direction from the reticle to the wafer, and f₄₂ is a focal length of the lens disposed downerstream in the direction from the reticle to the wafer.

Preferably, the projection objective is made of at least two groups of high refractive index mateirals and at least two groups of low refractive index mateirals.

Preferably, the high refractive index mateirals are mateirals having a refractive index of higher than 1.55 at I-line, including a first material group whose materials have refractive indices which are higher than 1.55 at I-line and Abbe numbers which are higher than 45 and a second material group whose materials have refractive indices which are higher than 1.55 at I-line and Abbe numbers which are higher than 50; the low refractive index mateirals are mateirals having a refractive index of lower than 1.55 at I-line, including a third material group whose materials have refractive indices which are lower than 1.55 at I-line and Abbe numbers which are lower than 55 and a fourth material group whose materials have a refractive indices which are lower than 1.55 at I-line and Abbe numbers which are higher than 60.

Preferably, both of a first lens of the first lens group G31 and a last lens of the fourth lens group G34 are made of a material of the first material group.

Preferably, each of the first, second, third and fourth lens groups includes at least one lens made of the a material of the first or second material group.

Preferably, each of the first, second and fourth lens groups includes at least one lens made of a material of the first material group.

Preferably, the third lens group includes at least one lens made of a material of the second material group.

Preferably, the second lens group includes at least one pair of lenses each of which has a convace surface facing a convace surface of the other lens. Additionally, the third lens group includes at least one meniscus lens which has a concanve surface facing an image plane. Moreover, the fourth lens group includes at least one meniscus lens which has a concave surface facing an object plane.

The present invention achieves, with a smaller number of lenses, a 2× projection objective for lithography which has a partial field of view of not smaller than 100 mm and is suited for I-line light with a wavelength band of +5 nm which can ensure a sufficient exposure light intensity. At the same time, the present invention also achieves, with a relatively simple structure, the demanded millimeter-level resolution as well as the correction of distortions, field curvatures, astigmatisms and chromatic aberrations in a large field.

### BRIEF DESCRIPTION OF THE DRAWINGS

To provide a more complete understanding of the present invention and its advantages, reference is made to the following detailed description on example embodiments, taken in conjunction with the accompanying drawings, in which:

FIG. 1 schematically illustrates the optical structure of a projection objective for lithography according to an embodiment of the present invention;

FIG. 2 shows a curve representing the distortions in an embodiment of the present invention;

FIG. 3 shows curves representing telecentricity on the object and image sides in an embodiment of the present invention; and

FIG. 4 shows curves representing aberrations in an embodiment of the present invention.

### DETAILED DESCRIPTION

Several exemplary embodiments of the present invention will be described below with reference to the accompanying drawings.

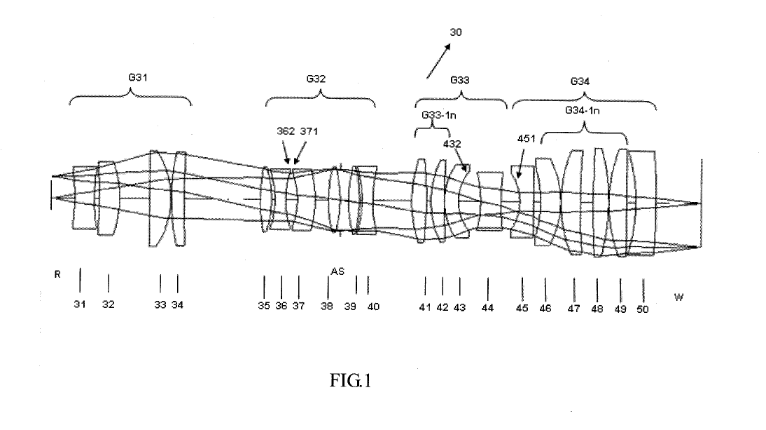

Referring to FIG. 1, a projection objective 30 according to an embodiment of the present invention includes twenty lenses, and specifications of which are shown in the following Table 1.

TABLE 1

| | |
|---|---|
| Working Wavelength | @365 nm ± 5 nm |
| Image-side Numerical Aperture | 0.1 |
| (NA) | |
| Magnification | −2 |
| Image-side Filed of View | 200 mm |
| (diameter) | |
| Object-Image Distance | 1500 mm |

The projection objective 30 is composed of twenty lenses. The twenty lenses are all spherical lenses and can be divided into four lens groups G31, G32, G33 and G34 each having a positive refractive power.

The first lens group G31 consists of four lenses, refractive powers of which are negative, positive, positive and positive, respectively.

The second lens group G32 consists of six lenses, refractive powers of which are positive, negative, negative, positive, positive and negative, respectively. Moreover, the second lens group G32 includes at least two pairs of lenses each consisting of a positive lens and a negative lens adjacent to the positive lens. Furthermore, the second lens group G32 includes at least one pair of lenses each of which has a convace surface facing a convace surface of the other lens.

The third lens group G33 consists of four lenses, refractive powers of which are positive, positive, negative and negative, respectively. Additionally, the third lens group G33 includes a sub-lens group G33-1n having a positive refractive power, the sub-lens group G33-1n including at least two adjacent lenses of the third lens group G33 both of which have a positive refractive power. Moreover, the third lens group G33 includes at least one meniscus lens which has a concanve surface facing an image plane.

The fourth lens group G34 consists of six lenses, refractive powers of which are negative, positive, positive, positive, positive and negative, respectively. Moreover, the fourth lens group G34 includes a sub-lens group G34-1n having a positive refractive power, the sub-lens group G34-1n including at least three directly successively arranged lenses of the fourth lens group G34 all of which have a positive refractive power. In addition, the fourth lens group G34 includes at least one meniscus lens which has a concanve surface facing an object plane.

The projection objective 30 is made of at least two groups of high refractive index mateirals and at least two groups of low refractive index mateirals, wherein the high refractive index mateirals may be those having a refractive index of higher than 1.55 for I-line light, including a first material group whose materials have refractive indices which are higher than 1.55 at I-line and Abbe numbers which are higher than 45 and a second material group whose materials have refractive indices which are higher than 1.55 at I-line and Abbe numbers which are higher than 50, while the low refractive index mateirals may be those having a refractive index of lower than 1.55 at I-line, including a third material group whose materials have refractive indices which are lower than 1.55 at I-line and Abbe numbers which are lower than 55 and a fourth material group whose materials have refractive indices which are lower than 1.55 at I-line and Abbe numbers which are higher than 60.

In a preferred embodiment, each of the first, second, third and fourth lens groups includes at least one lens made of a material of the first or second material group. Each of the first, second and fourth lens groups includes at least one lens made of the a material of first material group. The third lens group includes at least one lens made of a material of the second material group. Furthermore, both of a first lens of the first lens group G31 and a last lens of the fourth lens group G34 are preferably made of a material of the first material group.

The first lens group G31 consists of four lenses 31, 32, 33 and 34, among which: the lens 31 is a biconcave negative lens; the lens 32 is a positive meniscus lens having a concave surface facing a reticle surface R; and both the lenses 33 and 34 are positive lenses. Moreover, the lenses 31, 32 and 34 are each made of a material of the first or third material group while the lens 33 is made of a material of the second or fourth material group.

The second lens group G32 consists of six lenses 35, 36, 37, 38, 39 and 40, among which: the lens 35 is a biconvex positive lens; the lenses 36 and 37 are negative lenses, and the lens 36 has a concave surface 362 facing a concave surface 371 of the lens 37; the lenses 38 and 39 are positive lenses; and the lens 40 is a negative lens. Additionally, lenses 35, 36, 38 and 39 are each made of a material of the second or fourth material group while lenses 37 and 40 are each made of a material of the first or third material group.

The third lens group G33 consists of four lenses 41, 42, 43 and 44, among which: both the lenses 41 and 42 have a positive refractive power; both the lenses 43 and 44 have a negative refractive power; and the lens 43 is a meniscus lens having a concave surface 432 facing a wafer surface. Moreover, all the lenses 41, 42, 43 and 34 are each made of a material of the second or fourth material group.

The fourth lens group G34 consists of six lenses 45, 46, 47, 48, 49 and 50, refractive powers of which are negative, positive, positive, positive, positive and negative, respectively. The lens 45 has a flat rear surface and a concave surface facing the reticle surface. In addition, the lenses 45 and 47 are each made of a material of the second or fourth material group while the lenses 46, 48, 49 and 50 are each made of a material of the first or third material group.

Relationship among parameters of the lens groups G31, G32, G33 and G34 and their sub-lens groups can be expressed by the following formulae which further determines basic conditions for optimizing the imaging quality of the projection objective,

1.8<|f_{G32}/f_{G31}|<5.4 (1)

0.57<|f_{G33}/f_{G34}|<0. 97 (2)

0.19<|f_{G33}/f_{G32}|<0.5 (3)

1.03<|fₑₗ_{_{—}}ₘₐₓf_{G31}|<1.95 (4)

0.34<|f_{G33-1n}/f_{G33}|<0.87 (5)

0.21<|f_{G34-1n}/f_{G34}|<0.47 (6)

0.75<f₄₁/f₄₂<1 (7)

1.23<V_{G32-P}/V_{G32-N}<1.85 (8)

1.59<V_{G32-P}/V_{G32-N}<2.65 (9)

where: f_{G31} is a focal length of the first lens group G31; f_{G32} is a focal length of the second lens group G32; f_{G33} is a focal length of the third lens group G33; f_{G34} is a focal length of the fourth lens group G34; fₑₗ_{_{—}}ₘₐₓ is a focal length of a lens of the first lens group G31 which has a greatest refractive power in the first lens group G31; f_{G33-1n} is a focal length of the sub-lens group G33-1n of the third lens group G33; f_{G34-1n} is a focal length of the sub-lens group G34-1n of the fourth lens group G34; f₄₁ is a focal length of the lens 41 that is disposed upstream in the direction from the reticle to the wafer of the two adjacent lenses 41 and 42 of the sub-lens group G33-1n of the third lens group G33, while f₄₂ is a focal length of the other lens 42 that is disposed downstream in the direction; and V_{G32-P} and V_{G32-N} are Abbe numbers of a positive lens of the second lens group G32 and a negative lens of the second lens group G32 that is adjacent to the positive lens, respectively.

As described above, in this embodiment, focal lengths of the positive lenses 41 and 42 of the sub-lens group G33-1n of the third lens group G33 are indicated as f₄₁ and f₄₂ according to a relationship between their positions in the direction from the reticle to the wafer and satisfy the formula f₄₁<f₄₂. These two positive lenses are used to gradually compress the light eminated from the second lens group and thus improve the correction of field curvatures.

Moreover, the foregoing formulae (1) to (9) have defined structural relations of the lens groups G31, G32, G33, G34 and their sub-lens groups in correcting aberrations.

Specific design values of the projection objective in this embodiment are given in Table 2, in which, a positive radius of a surface indicates that a center of curvature of the surface is on its right side, and similarly, a negative radius of a surface indicates that a center of curvature of the surface is on its left side; a thickness of an optical member or a spacing between two optical members is defined as a distance from a current surface to the next surface along the optical axis; and the unit of all dimensions is millimeter.

In Table 2, there is further indicated: surface number “S#”, aperture stop (AS) “STOP”, and infinity “INF” in the column of Radius.

TABLE 2

| S | | Thicknesses and | | |
|---|---|---|---|---|
| # | Radii | Spacings | Materials | Remarks |
| OBJ | INF | 47.0004 | | Object-side |
| | | | | Working Distance |
| 1 | −341.576 | 34.29386 | PBL25Y | L1 |
| 2 | 1185.168 | 12.21087 | | |
| 3 | −222.541 | 45.3383 | PBM18Y | L2 |
| 4 | −161.39 | 71.85194 | | |
| 5 | INF | 47.00983 | SFSL5Y | L3 |
| 6 | −183.839 | 1 | | |
| 7 | 844.4744 | 26.49825 | PBL25Y | L4 |
| 8 | INF | 194.2484 | | |
| 9 | 414.9022 | 26.25041 | SFSL5Y | L5 |
| 10 | −243.136 | 6.168656 | | |
| 11 | −176.468 | 23 | BSM51Y | L6 |
| 12 | 254.7796 | 31.33048 | | |
| 13 | −178.33 | 44.40986 | PBM18Y | L7 |
| 14 | −232.626 | 29.66318 | | |
| 15 | 403.048 | 25.85819 | SFSL5Y | L8 |
| 16 | −230.792 | 1 | | |
| 17 | INF | 30.67998 | | (STOP) |
| 18 | 313.9001 | 25.88924 | SFSL5Y | L9 |
| 19 | −331.934 | 6.301843 | | |
| 20 | −270.11 | 23 | PBM18Y | L10 |
| 21 | 288.0486 | 64.21258 | | |
| 22 | 329.4014 | 27.44817 | SFSL5Y | L11 |
| 23 | −680.652 | 2.530852 | | |
| 24 | 186.3488 | 28.49718 | BSL7Y | L12 |
| 25 | 3221.473 | 1.000735 | | |
| 26 | 161.8902 | 29.67068 | BSM51Y | L13 |
| 27 | 105.8729 | 64.02459 | | |
| 28 | −238.698 | 48.93309 | BSM51Y | L14 |
| 29 | 389.3077 | 38.0038 | | |
| 30 | −117.901 | 23 | BSM51Y | L15 |
| 31 | INF | 20.13205 | | |
| 32 | −320.124 | 46.94477 | PBM18Y | L16 |
| 33 | −226.249 | 4.830725 | | |
| 34 | 317.7772 | 49.397 | BSL7Y | L17 |
| 35 | 5543.824 | 32.52187 | | |
| 36 | 345.6422 | 49.34704 | PBM18Y | L18 |
| 37 | −1234.86 | 1 | | |
| 38 | 330.8498 | 49.41093 | PBM18Y | L19 |
| 39 | INF | 27.72791 | | |
| 40 | −434.844 | 37.4797 | PBM18Y | L20 |
| 41 | −12935.3 | 100.8894 | | Image-side |
| | | | | Working Distance |
| IMG | INF | 0 | | |

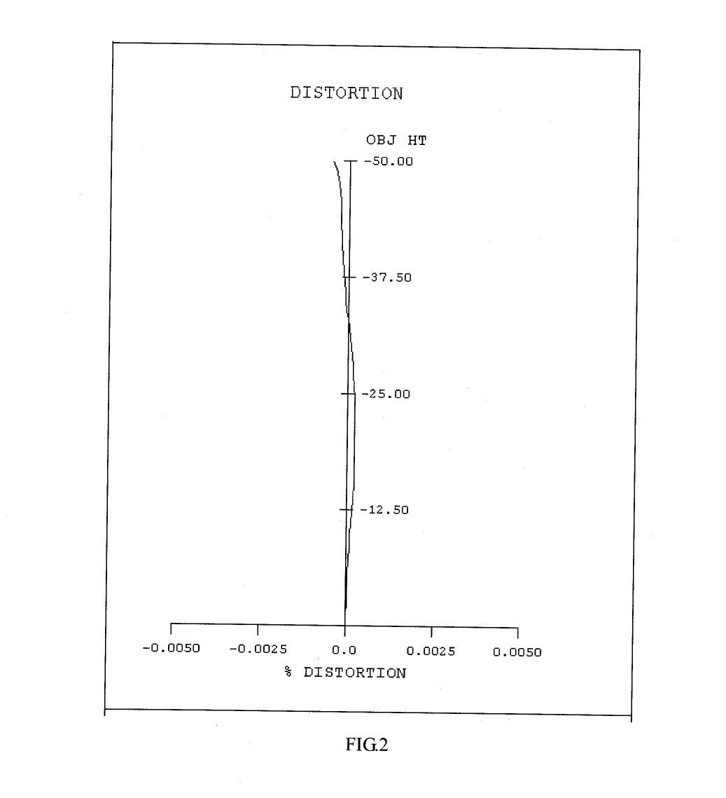

FIG. 2 shows that the projection objective 30 of this embodiment has a good performance in distortion inhibition.

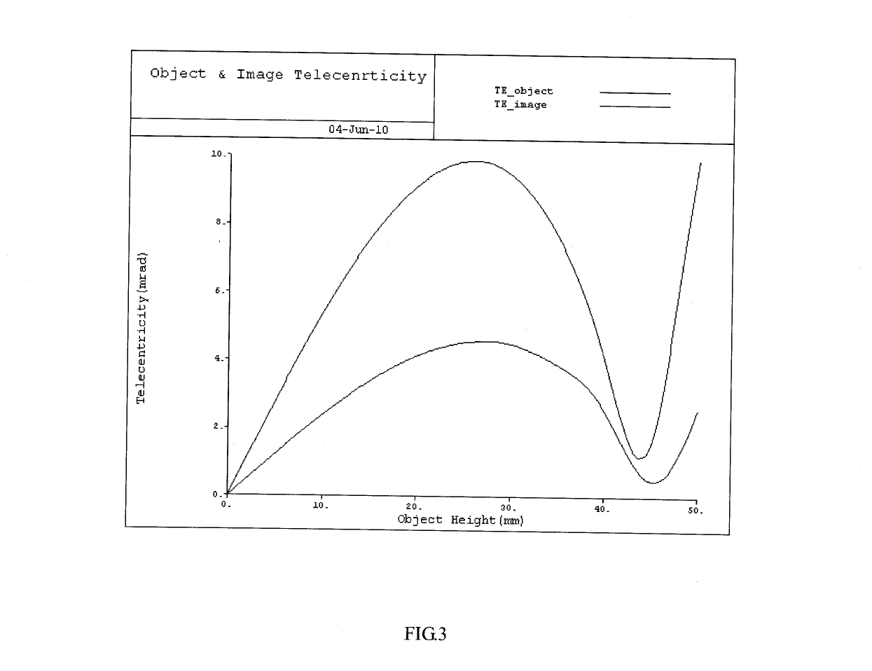

FIG. 3 shows that telecentricity is corrected to about 3 mrad on the object side and to about 10 mrad on the image side of the projection objective 30.

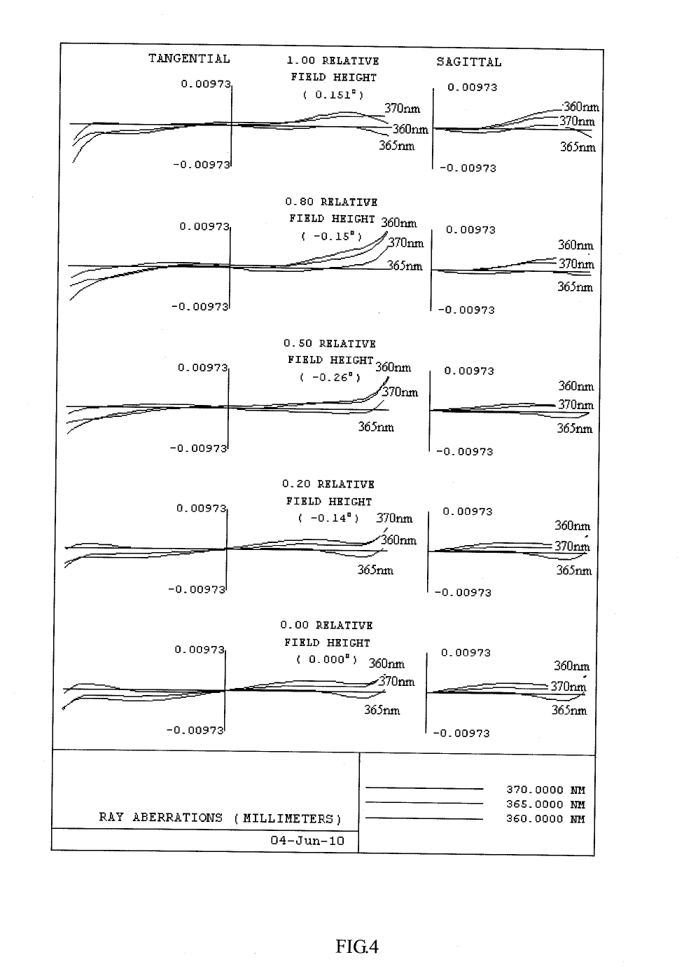

Moreover, the aberration curves in FIG. 4 indicate that the projection objective 30 has a good performance in image quality correction, and that a high quality of images at I-line±5 nm has been achieved.

In a word, the projection objectives described in the description are merely several preferable embodiments of the invention which are provided solely for the purpose of describing but not limiting the invention in any way. Any technical solutions which are obtained by those skilled in the art through logical analysis, reasoning or limited experiment in light of the conception of the invention are within the scope as defined in the appended claims.

What is claimed is:

1. A lithography projection objective for focusing and imaging a pattern of a reticle onto a wafer comprising, from the reticle and along an optical axis:
a first lens group G31 having a positive refractive power;
a second lens group G32 having a positive refractive power;
a third lens group G33 having a positive refractive power; and
a fourth lens group G34 having a positive refractive power,
wherein the following formulae are satisfied:
1. 8<|f_{G32}/f_{G31|<5.4}
0.57<|f_{G33}/f_{G34}|<0.97
0.19<|f_{G33}/f_{G32}|<0.5
where f_{G31} is a focal length of the first lens group G31, f_{G32} is a focal length of the second lens group G32, f_{G33} is a focal length of the third lens group G33, and f_{G34} is a focal length of the fourth lens group G34.

2. The lithography projection objective according to claim 1, wherein:
the first lens group G31 comprises at least four lenses;
the second lens group G32 comprises at least six lenses which includes at least two pairs of lenses each consisting of a positive lens and a negative lens adjacent to the positive lens;
the third lens group G33 comprises at least four lenses and includes a sub-lens group G33-1n having a positive refractive power, the sub-lens group G33-1n including at least two adjacent lenses of the third lens group G33 both of which have a positive refractive power;
the fourth lens group G34 comprises at least six lenses and includes a sub-lens group G34-1n having a positive refractive power, the sub-lens group G34-1n including at least three directly successively arranged lenses of the fourth lens group G34 all of which have a positive refractive power; and
the following formulae are satisfied:
1.03<|fₑₗ_{_{—}}ₘₐₓ/f_{G31}|<1.95
0.34<|f_{G33-1n}/f_{G33}|<0.87
0.21<|f_{G34-1n}/f_{G34}|<0.47
where fₑₗ_{_{—}}ₘₐₓ is a focal length of a lens of the first lens group G31 which has a greatest refractive power in the first lens group G31, f_{G33-1n} is a focal length of the sub-lens group G33-1n of the third lens group G33, and f_{G34-1n} is a focal length of the sub-lens group G34-1n of the fourth lens group G34.

3. The lithography projection objective according to claim 2, wherein the second lens group G32 includes at least a positive lens and a negative lens directly adjacent to the positive lens, and wherein the following formula is satisfied:
1.23<V_{G32-P}/V_{G32-N}<1.85
where V_{G32-P} is an Abbe number of the positive lens of the second lens group G32, and V_{G32-N} is an Abbe number of the negative lens of the second lens group G32 that is directly adjacent to the positive lens.

4. The lithography projection objective according to claim 2, wherein the second lens group G32 includes at least a positive lens and a negative lens directly adjacent to the positive lens, and wherein the following formula is satisfied:
1.59<V_{G32-P}/V_{G32-N}<2.65
where V_{G32-P} is an Abbe number of the positive lens of the second lens group G32, and V_{G32-N} is an Abbe number of the negative lens of the second lens group G32 that is directly adjacent to the positive lens.

5. The lithography projection objective according to claim 1, wherein among the two adjacent positive lenses of the sub-lens group G₃₃₋₁ₙ of the third lens group G33, the one disposed downstream in a direction from the reticle to the wafer has a greater focal length, and wherein the focal lengths of the two adjacent positive lenses are both within a range of 0.75 to 1.

6. The lithography projection objective according to claim 2, wherein the projection objective is made of at least two groups of high refractive index mateirals and at least two groups of low refractive index mateirals.

7. The lithography projection objective according to claim 6, wherein:
the high refractive index mateirals are mateirals having a refractive index of higher than 1.55 at I-line, including a first material group whose materials have refractive indices which are higher than 1.55 at I-line and Abbe numbers which are higher than 45 and a second material group whose materials have refractive indices which are higher than 1.55 at I-line and Abbe numbers which are higher than 50;
the low refractive index mateirals are mateirals having a refractive index of lower than 1.55 at I-line, including a third material group whose materials have refractive indices which are lower than 1.55 at I-line and Abbe numbers which are lower than 55 and a fourth material group whose materials have a refractive indices which are lower than 1.55 at I-line and Abbe numbers which are higher than 60.

8. The lithography projection objective according to claim 7, wherein each of the first, second, third and fourth lens groups includes at least one lens made of a material of the first or second material group.

9. The lithography projection objective according to claim 7, wherein each of the first, second, and fourth lens groups includes at least one lens made of a material of the first material group.

10. The lithography projection objective according to claim 9, wherein both of a first lens of the first lens group G31 and a last lens of the fourth lens group G34 are made of a material of the first material group.

11. The lithography projection objective according to claim 7, wherein the third lens group includes at least one lens made of a material of the second material group.

12. The lithography projection objective according to claim 7, wherein:
the second lens group includes at least one pair of lenses which have convace surfaces facing each other;
the third lens group includes at least one meniscus lens which has a concanve surface facing an image plane; and
the fourth lens group includes at least one meniscus lens which has a concanve surface facing an object plane.
